(19) United States
(12) Patent Application Publication
(10) Pub. No.: US 2013/0074770 A1
(43) Pub. Date: Mar. 28, 2013

(54) FILM DEPOSITION APPARATUS AND SUBSTRATE PROCESSING APPARATUS

(71) Applicant: Manabu HONMA, Iwate (JP)

(72) Inventor: Manabu HONMA, Iwate (JP)

(73) Assignee: Tokyo Electron Limited, Tokyo (JP)

(21) Appl. No.: 13/622,582

(22) Filed: Sep. 19, 2012

(30) Foreign Application Priority Data
Sep. 22, 2011 (JP) 2011-207990

(51) Int. Cl. C23C 16/458

(52) U.S. Cl. 118/719

(57) ABSTRACT

A film deposition apparatus includes processing areas spaced part from each other in a circumferential direction and at least one separation gas nozzle arranged between the process areas, and separates the process areas from each other by supplying a separation gas from the separation gas nozzle. Moreover, a first ceiling surface is provided on the downstream side in a rotational direction of the turntable relative to the separation gas nozzle to form a narrow space between an upper surface of the turntable and a lower surface of the first ceiling surface. Furthermore, a second ceiling surface higher than the first ceiling surface is provided on the upstream side in the rotational direction of the turntable.

### CROSS-REFERENCE TO RELATED APPLICATIONS

This patent application is based upon and claims the benefit of priority of Japanese Patent Application No. 2011-207990, filed on Sep. 22, 2011, the entire contents of which are incorporated herein by reference.

### BACKGROUND OF THE INVENTION

1. Field of the Invention

The present invention relates to a film deposition apparatus and a substrate processing apparatus that deposit a reaction product on a surface of a substrate in a layer-by layer manner by supplying process gases that react with each other.

2. Description of the Related Art

An apparatus is known that deposits a thin film such as a silicon oxide film (SiO₂) on a substrate such as a semiconductor wafer (which is hereinafter called a “wafer”) by using an ALD (Atomic Layer Deposition) method. As disclosed in Japanese Patent Application Laid-Open Publication No. 2010-239102, for example, such an apparatus has a configuration in which a turntable on which plural wafers are arranged in a circumferential direction is rotated and provided in a vacuum chamber. In this apparatus, process gases that react with each other are supplied from plural gas supplying parts provided facing the turntable onto the wafers in turn.

In such an apparatus, for example, an N₂ (nitrogen) gas is supplied as a separation gas to a location between areas where a process gas is supplied in order to separate these areas from each other. At this time, if the separation gas is supplied at a greater flow rate, a running cost of the apparatus (i.e. , cost of the separation gas) increases. Moreover, there is a concern that the process gases are diluted by the separation gas. In contrast, if the flow rate of the separation gas is assumed to be reduced, there is a concern that the process gases are mixed with each other in a processing atmosphere.

U.S. Pat. No. 7,153,542, Japanese Patent No. 3144664, and U.S. Pat. No. 6,869,641 disclose apparatuses that deposit a thin film by the ALD method, but do not disclose measures to address the above mentioned concerns.

### SUMMARY OF THE INVENTION

Embodiments of the present invention provide a novel and useful film deposition apparatus and a substrate processing apparatus solving one or more of the problems discussed above.

More specifically, embodiments of the present invention provide a film deposition apparatus and a substrate processing apparatus that can reduce a flow rate of a separation gas, preventing process gases from being mixed with each other in a processing atmosphere by supplying the separation gas to a. location between process areas to which the process gases are respectively supplied, in depositing a reaction product on a surface of a substrate in a layer-by-layer manner by supplying the process gases that react with each other in turn.

According to one embodiment of the present invention, there is a film deposition apparatus configured to form a thin film on a wafer by repeating a cycle of supplying plural kinds of process gases in turn in a vacuum chamber. The film deposition apparatus includes a turntable having a substrate mounting area in an upper surface to hold a substrate thereon in a circumferential direction, the turntable being configured to make the substrate mounting area revolve in the vacuum chamber, a plurality of process gas supplying parts configured to supply process gases different from each other to process areas spaced apart from each other in the circumferential direction of the turntable, at least one separation part including a separation gas nozzle arranged to extend from a center side to an outer circumference side of the turntable to supply a separation gas to a separating area formed between the process areas for separating atmospheres of the respective process areas, and at least one evacuation opening configured to evacuate an atmosphere in the vacuum chamber, the evacuation opening being provided at an outer edge side of the turntable. The separation part includes a first ceiling surface provided on the downstream side in the rotational direction of the turntable relative to the separation gas nozzle, the first ceiling surface being configured to form a narrow space between a lower surface thereof and the upper surface of the turntable from the center side to the outer circumference side of the turntable, and includes a second ceiling surface provided on the upstream side in the rotational direction of the turntable relative to the separation gas nozzle, the second ceiling surface being configured to be higher than the first ceiling surface from the center side to the outer circumference side. The evacuation opening is in communication with a gas retention space to be an area between the second ceiling surface and the turntable.

According to another embodiment of the present invention, there is a substrate processing apparatus configured to perform a process on a wafer by repeating a cycle of supplying plural kinds of process gases in turn in a vacuum chamber. The substrate processing apparatus includes a turntable having a substrate mounting area in an upper surface to hold a substrate thereon in a circumferential direction, the turntable being configured to make the substrate mounting area revolve in the vacuum chamber, a plurality of process gas supplying parts configured to supply process gases different from each other to process areas spaced apart from each other in the circumferential direction of the turntable, at least one separation part including a separation gas nozzle arranged to extend from a center side to an outer circumference side of the turntable to supply a separation gas to a separating area formed between the process areas for separating atmospheres of the respective process areas, and at least one evacuation opening configured to evacuate an atmosphere in the vacuum chamber, the evacuation opening being provided at an outer edge side of the turntable. The separation part includes a first ceiling surface provided on the downstream side in the rotational direction of the turntable relative to the separation gas nozzle, the first ceiling surface being configured to form a narrow space between a lower surface thereof and the upper surface of the turntable from the center side to the outer circumference side of the turntable, and includes a second ceiling surface provided on the upstream side in the rotational direction of the turntable relative to the separation gas nozzle, the second ceiling surface being configured to be higher than the first ceiling surface from the center side to the outer circumference side. The evacuation opening is communication with a gas retention space to form an area between the second ceiling surface and the turntable.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a vertical cross-sectional view showing an example of a film deposition apparatus of an embodiment of the present invention;

FIG. 2 is a horizontal cross-sectional view of the film deposition apparatus of the embodiment;

FIG. 3 is a cross-sectional view of the film deposition apparatus of the embodiment;

FIG. 4 is a perspective view schematically showing a part of the film deposition apparatus of the embodiment;

FIG. 5 is a vertical cross-sectional view showing a part of the film deposition apparatus of the embodiment;

FIG. 6 is a vertical cross-sectional view showing a part of the film deposition apparatus of the embodiment;

FIG. 7 is a vertical cross-sectional view showing a part of the film deposition apparatus of the embodiment;

FIG. 8 is an exploded perspective view showing a part of the film deposition apparatus of the embodiment;

FIG. 9 is a vertical cross-sectional view showing a part of an action of the film deposition apparatus of the embodiment;

FIG. 10 is a vertical cross-sectional view showing an action of the film deposition apparatus of the embodiment;

FIG. 11 is a horizontal cross-sectional view showing an action of the film deposition apparatus of the embodiment;

FIG. 12 is a characteristic diagram showing a characteristic of a thin film obtained by the film deposition apparatus of the embodiment; and

FIG. 13 is a partial exploded and enlarged diagram showing another example of the film deposition apparatus of an embodiment.

### DETAILED DESCRIPTION OF THE PREFERRED EMBODIMENTS

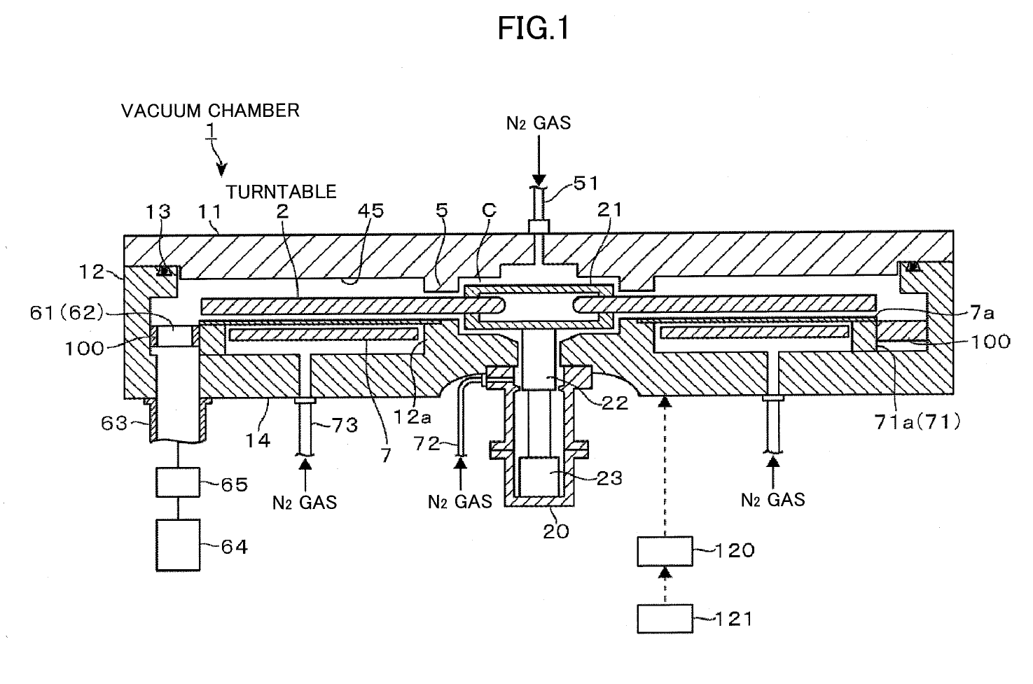

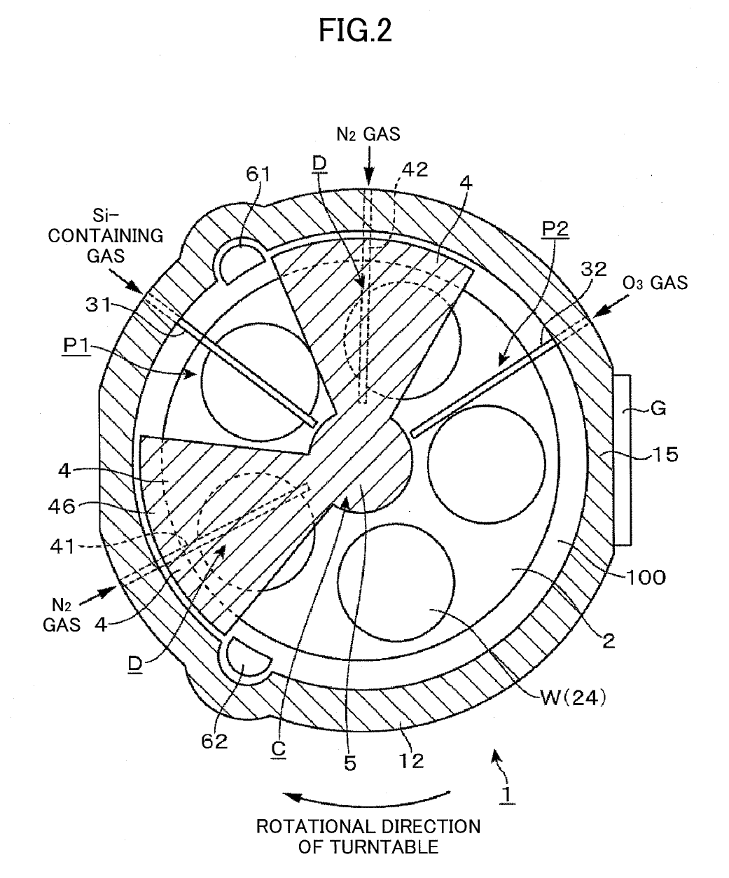

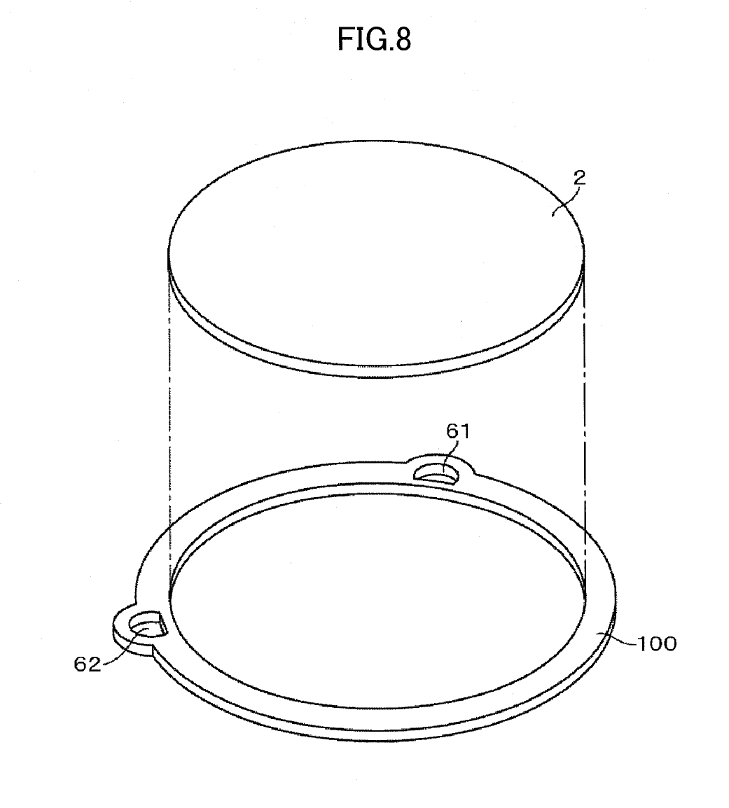

A description is given below, with reference to drawings of embodiments of the present invention. More specifically, a description is given about an example of a substrate processing apparatus of an embodiment of the present invention with reference to FIGS. 1 through 8. As shown in FIGS. 1 and 2, a film deposition apparatus of an embodiment of this substrate processing apparatus includes a vacuum chamber 1 whose planar shape is an approximately round shape, and a turntable 2 provided in the vacuum chamber 1 and having the rotation center that coincides with the center of the vacuum chamber 1. As described below in detail, the film deposition apparatus deposits a thin film by supplying plural process gases that react with each other, for example, two kinds of process gases, on a wafer W by an ALD method, and sections areas to which these process gases are respectively supplied by using a separation gas. At this time, a supply flow rate of the separation gas is kept low so that the process gases are substantially prevented from being mixed with each other in the processing atmosphere. Next, a description is given about respective parts of the film deposition apparatus.

The vacuum chamber 1 includes a ceiling plate 11 and a chamber body 12, and is configured to allow the ceiling plate 11 to be detachable from the chamber body 12. A separation gas supplying pipe 51 for supplying an N₂ (nitrogen) gas as a separation gas is connected to the center portion on the top surface of the ceiling plate 11 in order to suppress mixture of different process gases with each other in a center area C in the vacuum chamber 1. In FIG. 1, a numeral 13 shows a seal member provided in a ring form in an outer edge in the top surface of the chamber body 12 such as an O-ring. A protrusion portion 5 protruding downward from the ceiling plate 11 and extending in a ring form is formed on the outside of the area to which the separation gas is supplied in the vacuum chamber 1.

The turntable 2 is fixed to a core part 21 having an approximately cylindrical shape at the center portion, and is configured to be rotatable around a vertical axis, for example, in a clockwise direction in this example, by a rotational shaft 22 that is connected to the bottom surface of the care part 21 and extends in a vertical direction. In FIG. 1, a drive part 23 rotates the rotational shaft 22 around the vertical axis, and a case body 20 houses the rotational shaft 22 and the drive part 23. A purge gas supplying pipe 72 for supplying an N₂ gas as a purge gas to an area below the turntable 2 is connected to the case body 20. The outer circumference side of the core part 21 in the bottom part 14 of the vacuum chamber 1 is formed into a ring shape so as to come close to the turntable 2 from the lower side and forms as a protrusion portion 12a. Here, the upstream side in the rotational direction and the downstream side in the rotational direction of the turntable 2 may be just called “the upstream side” and “the downstream side” respectively in the following description.

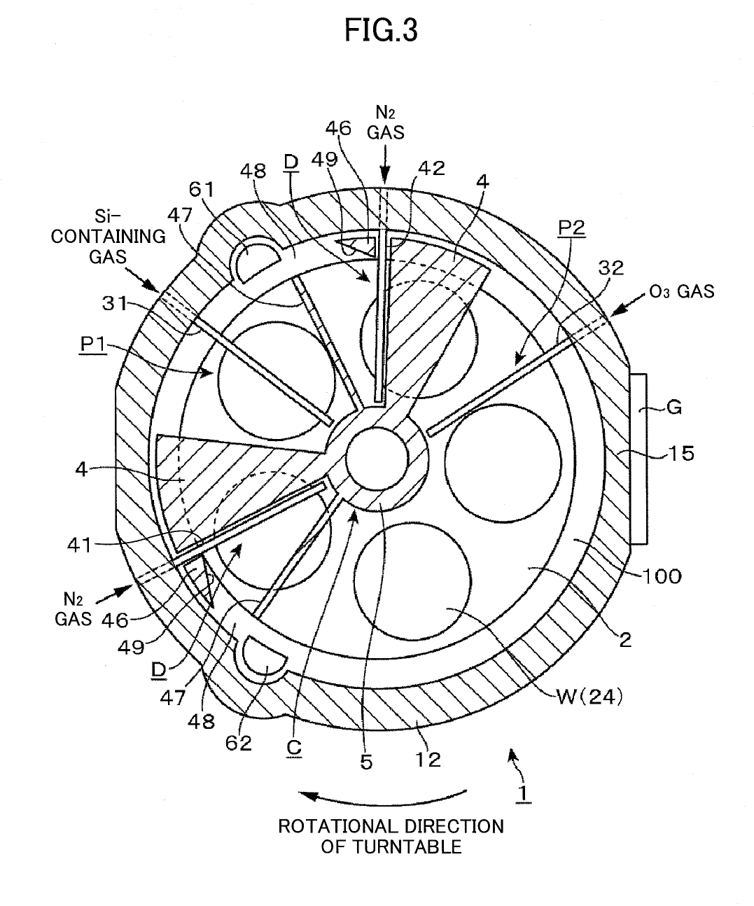

As shown in FIGS. 2 and 3, plural circular shaped concave portions 24 to hold wafers W, for example, 300 mm in diameters thereon, are provided at plural places, for example, five places, along a rotational direction (a circumferential direction) as substrate loading areas in the surface of the turntable 2. A size in diameter and depth of the concave portions 24 is set so that the surface of the wafer W and the surface of the turntable 2 (i.e., a region where the wafer W is not loaded) are even when the wafer W is dropped down (held) into the concave portion 24. In the bottom surface of the concave portion 24, three through holes are formed (which are not shown in the drawings) through which pass, for example, corresponding lift pins described below to move the wafer W up and down by pushing up the wafer W from the lower side.

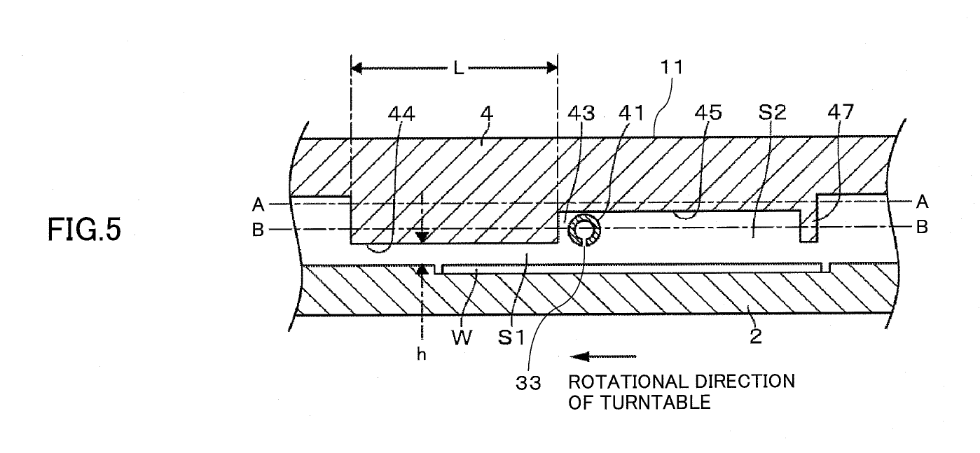

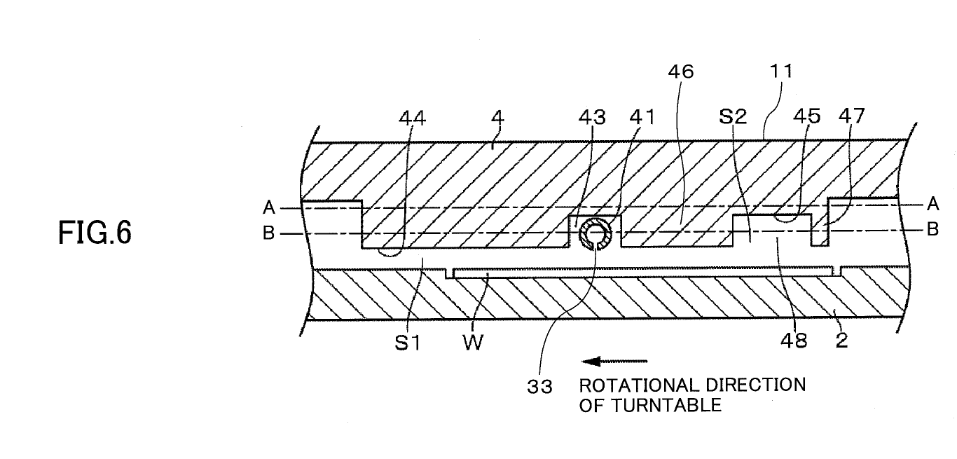

As shown in FIGS. 2 and 3, at positions opposite to areas where the concave portions 24 in the turntable 2 pass through by the rotation, for example, four nozzles 31, 32, 41 and 42 respectively made of quartz are arranged in a radial fashion, at intervals with each other in a circumferential direction of the vacuum chamber 1, (i.e., in a rotational direction of the turntable 2) . These nozzles 31, 32, 41 and 42 are, for example, respectively installed so as to extend horizontally toward the center area C from an outer peripheral wall of the vacuum chamber 1, facing the wafer W. In this example, a separation gas nozzle 41, a first process gas nozzle 31, a separation gas nozzle 42, and a second process nozzle 32 are arranged in this order in a clockwise fashion (i.e., in a rotational direction of the turntable 2) when seen from a transfer opening 15 described below. Here, FIG. 2 shows a horizontal cross-section that cuts the vacuum chamber 1 along A-A lines in FIGS. 5 and 6, and FIG. 3 shows a horizontal cross-section that cuts the vacuum chamber 1 along B-B lines in FIGS. 5 and 6. Moreover, internal structures are omitted with respect to the nozzles 31, 32, 41 and 42 in FIG. 3.

The nozzles 31, 32, 41 and 42 are respectively connected to the following gas supplying sources (which are not shown in the drawing) through flow control valves. More specifically, the first process gas nozzle 31 is connected to a source of a first process gas containing Si (silicon) such as a BTBAS
(bis (tertiary-butylaminosilane)):SiH₂(NH—C (CH₃)₂) gas. The second process gas nozzle 32 is connected to a supplying source of a second process gas such as a mixed gas of an O₂ gas and an O₃ gas (which is hereinafter called “an O₃ gas” for simplifying the name). The separation gas nozzles 41, 42 are respectively connected to a supplying source of an N₂ (nitrogen) gas to be a separation gas. The first process gas nozzle 31 and the second process gas nozzle 32 respectively form a first process gas supplying part and a second process gas supplying part. Furthermore, the separation gas nozzles 41, 42 respectively form separation gas supplying parts.

As shown in FIGS. 5 and 6, in the lower surface of the gas nozzles 31, 32, 41 and 42, gas discharge ports 33 are formed at plural points along a radial direction of the turntable 2, for example, at an equal distance. These respective nozzles 31, 32, 41 and 42 are arranged so that a distance between the lower end edge of the nozzles 31, 32, 41 and 42 and the top surface of the turntable 2 is, for example, about 1 to 5 mm. An area under the process gas nozzle 31 is a first process area P1 to adsorb the Si-containing gas onto the wafer W, and an area under the second process gas nozzle 32 is a second process area P2 to cause the Si-containing gas adsorbed on the wafer W to react with the O₃ gas. The separation gas nozzles 41, 42 are to form separating areas D that separate the first process area P1 from the second process area P2, respectively.

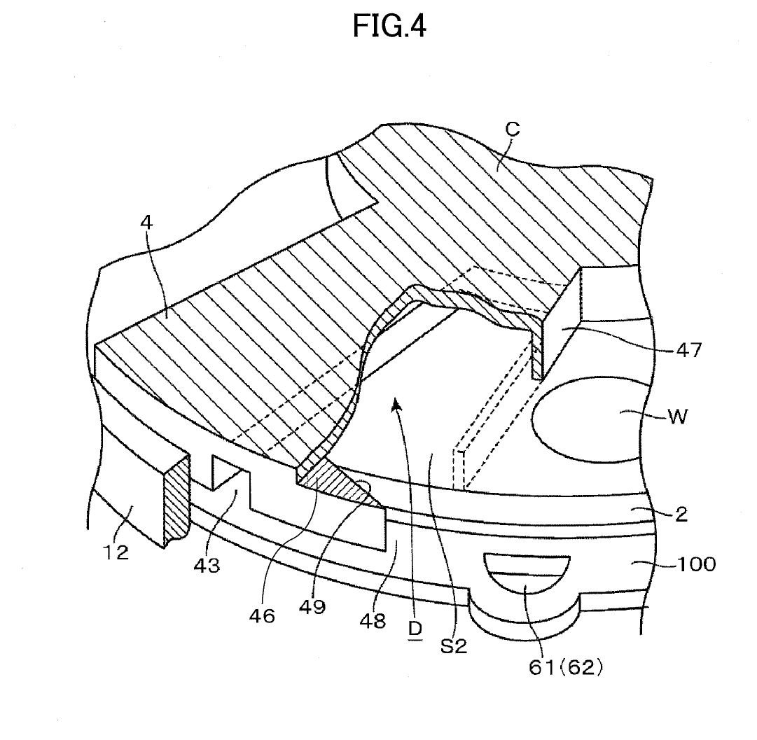

With respect to the two separating areas D, to begin with, a description is given about the separating area D where the separation gas nozzle 41 (the downstream side relative to the second process gas nozzle 32 and the upstream side relative to the first process gas nozzle 31) is provided. As shown in FIG. 2, on the upstream side and the downstream side of the separation gas nozzle 41 in the rotational direction of the turntable 2, convex portions 4, 4 that project downward from the ceiling plate 11 of the vacuum chamber 1 along the radial direction of the turntable 2 are respectively provided, and these convex portions 4, 4 are formed to spread in the rotational direction of the turntable 2 so as to be shaped into an approximate sector. Accordingly, the separation gas nozzle 41 is held in a groove portion 43 formed to extend in the radial direction of the turntable 2 between the convex portions 4, 4 (see FIGS. 4 through 7). As shown in FIGS. 2 and 3, regions on the rotation center side of the turntable 2 in the convex portions 4, 4 are connected to the convex portion 5. A width dimension L of the respective convex portions 4, 4 in the rotational direction of the turntable 2 is, for example, 50 mm at a position that the center portion of the wafer W passes.

The convex portion 4 on the downstream side in the rotational direction of the turntable 2 of the convex portions 4, 4 on both sides of the separation gas nozzle 41 is to prevent the process gas of the first process gas nozzle 31 on the downstream side of the convex portion 4 from flowing around to the separation gas nozzle 41 side. To do this, as shown in FIGS. 5 and 6, the lower end surface of this convex potion 4 is arranged to be close to the surface of the turntable 2 and forms a first ceiling surface 44 in order to create a narrow space S1 between it and the surface of the turntable 2. The first ceiling surface 44 is formed across from the center side to the outer circumference side of the turntable 2. A distance h between this first ceiling surface 44 and the turntable 2 is, for example, 0.5 mm to 10 mm, and about 4 mm in this example. The outer edge portion of this convex portion 4 (i.e., a region between the outer edge portion of the turntable 2 and the inner wall surface of the vacuum chamber 1), as shown in FIG. 4, is bent into a L letter so that a bent portion faces the outer edge surface of the turntable 2 and forms a bent portion 46 in order to prevent a gas from passing the outer edge side. A gap size between the bent portion 46 and the turntable 2 or a side ring 100 described below is set at the same degree as the above-mentioned distance h.

Here, in the area where the first process gas nozzle 31 is arranged to be the downstream area in the rotational direction of the turntable 2 relative to the first ceiling surface 44, as shown in FIGS. 5 and 6, the lower surface of the ceiling surface 11 is higher than the first ceiling surface 44. Hence, when seen from the first process gas nozzle 31 to the separation gas nozzle 41 side, because the narrow space S1 is formed across the radial direction of the turntable 2, and the separation gas of the separation gas nozzle 41 flows from the narrow space S1 toward the first gas nozzle 31, the first process gas is prevented from going around to the separation gas nozzle 41 side.

Next, a description is given about the convex portion 4 of the upstream side in the rotational direction of the turntable 2 of the convex portions 4, 4 on both sides of the separation gas nozzle 41. This convex portion 4 is, for example, to prevent the process gas discharged from the second process gas nozzle 32 from intruding into the narrow space S1, and creates a gas retention space (i.e., a cavity) S2 larger than the narrow space S1 so that the gas stagnates in the area under the convex portion 4. In other words, in the convex portion 4 as shown in FIGS. 3 and 5, a ceiling surface of the groove portion 43 housing the separation gas nozzle 41 extends in a horizontal direction toward the upstream side, and forms a second ceiling surface 45 higher than the first ceiling surface 44. Accordingly, the gas retention space S2 is formed across from the center side to the outer circumference side (i.e., in a radial direction) of the turntable 2, and forms a sector shape in a sense, so as to spread out in the rotational direction of the turntable 2. These first ceiling surface 44, second ceiling surface 45 and separation gas nozzle 41 constitute the separating part D. Incidentally, FIG. 5 shows a vertical cross-sectional view that cuts the vacuum chamber 1 in the circumferential direction at a location close to the center area C side of the turntable 2. FIG. 6 shows a vertical cross-sectional view that cuts the vacuum chamber 1 in the circumferential direction at a location outer than the outer edge portion of the turntable 2.

In addition, the end portion of this second ceiling surface 45 on the upstream side in the rotational direction of the turntable 2 vertically extends toward the turntable 2 and forms a wall surface portion 47 to prevent the process gas supplied from the second process gas nozzle 32 into the vacuum chamber 1 from intruding into the gas retention space S2. As shown in FIG. 3, the wall surface portions 47 are formed across from the center side to the outer circumference side of the turntable 2. More specifically, the wall surface portions 47 are arranged across from the protrusion portion 5 on the center side of the turntable 2 to a position facing the outer edge portion of the turntable 2. A distance between the wall surface portions 47 and the turntable 2 is set at about the same degree of size as the distance h.

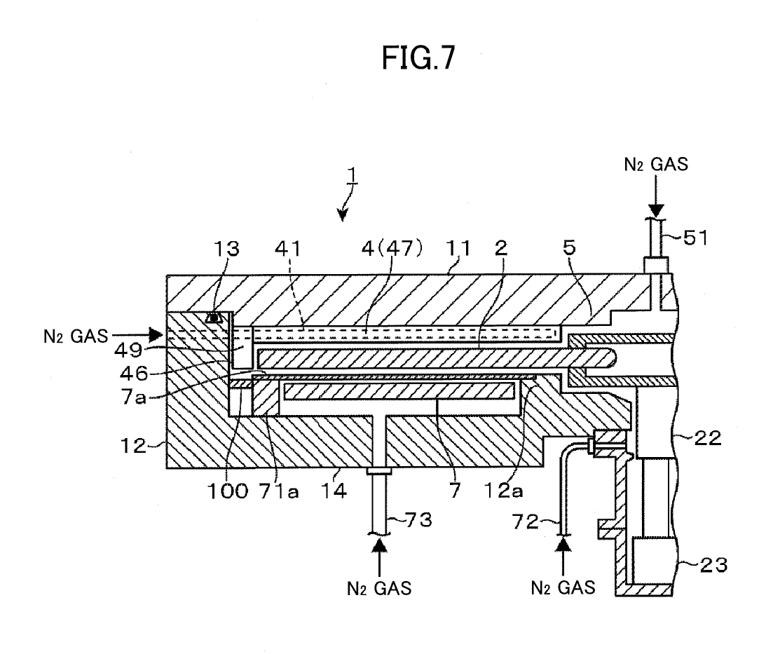

Moreover, as shown in FIGS. 3 and 6, in order to evacuate the gas in the gas retention space S2 to the outer circumference side of the turntable 2, a region on the upstream side in the direction of turntable 2 of the outer circumference surface of the convex portion 4 is cut off into an approximate rectangle, and forms an opening portion 48. Furthermore, a region on the outer circumference side of the convex portion 4 on the upstream side in the rotational direction of the turntable 2 relative to the opening portions 48, as shown in FIG. 7 to be a cross-sectional view in the radial direction, extends up to a location between the outer edge portion of the turntable 2 and the inner wall surface of the vacuum chamber 1, and forms the bent portion 46, as well as the convex portion 4 of the downstream side of the separation gas nozzle 41. Here in FIGS. 5 and 6, the bent portion 46 is omitted because of space limitations. FIG. 7 shows an aspect of the convex portion 4 as seen from the second gas nozzle side 32.

In addition, as shown in FIG. 3, the inner wall surface of the convex portion 4 facing the center area C between the opening portion 48 and the separation gas nozzle 41 extends from the lateral side of the separation gas nozzle 41 toward an evacuation port 62 described below, and forms a guide surface 49 in order to guide the separation gas discharged from the separation gas nozzle 41 toward the opening portion 48. In other words, with respect to the inner wall surface of the convex potion 4 on the downstream side of the opening portion 48, a region on the opening portion side is cut off at an angle toward the evacuation port 62 when seen from the top. Accordingly, the convex portion 4 (i.e., the bent portion 46) on the downstream side of the opening portion 48 is arranged in an area closer to the inner wall surface of the vacuum chamber 1 than the outer edge portion of the turntable 2, and a width of the convex portion 48 decreases away from the separation gas nozzle 41 to the opening portion 48. In addition, the guide surface 48 is formed to cross with a length direction of the separation gas nozzle 41.

In the separation gas nozzle 42, the convex portions 4, 4 are respectively arranged on the upstream side and the downstream side in the rotational direction of the turntable 2, and the narrow space S1 is formed at the convex portion 4 on the second process gas nozzle 32 side of these convex portions 4, 4. Moreover, at the convex portion 4 between the separation gas nozzle 42 and the first process gas nozzle 31, the gas retention space S2, the wall surface portion 47 and the guide surface 49 are formed. Here in FIG. 4, a part of the convex portion 4 is cut off, and the convex portion 4 is schematically drawn.

Subsequently, a description is given about the film deposition apparatus again. As shown in FIGS. 2, 3, 4 and 9, a side ring 100 to be a cover body is arranged on the outer circumferential side of the turntable 2 and slightly below the turntable 2. This side ring 100 is, for example, used in cleaning the film deposition apparatus, when a fluorine-system cleaning gas is used instead of respective process gasses, to protect the inner wall of the vacuum chamber 1 from the cleaning gas. In other words, it can be said that a concave air flow passage that can form an air flow (exhaust flow) in a transverse direction is formed in a ring shape along the circumferential direction between the outer circumferential portion of the turntable 2 and the inner wall of the vacuum chamber 1 if the side ring 100 is not provided. To prevent this, the side ring 100 is provided in the air flow passage in order to minimize exposure of the inner wall of the vacuum chamber 1 to the air flow passage. In this example, an area on the outer edge side of the respective separating areas D (i.e., the bent portion 46) extends facing the side ring 100.

In the top surface of the side ring 100, evacuation openings 61, 62 are formed at two places so as to be away from each other in the circumferential direction. In other words, the two evacuation ports are formed below the air flow passage, and the evacuation openings 61, 62 are formed at places corresponding to the evacuation ports in the side ring 100. Among the two evacuation openings 61, 62, if one and the other are respectively called a first evacuation opening 61 and a second evacuation opening 62, as shown in FIG. 2, the first evacuation opening 61 is formed, between the first process gas nozzle 31 and the convex portion 4 on the downstream side in the rotational direction of the turntable 2 relative to the first process gas nozzle 31, at a location closer to the separating area D side. Accordingly, as shown in FIG. 3, the first evacuation opening 61 is arranged so as to be in communication with the gas retention space S2 between the first evacuation opening 61 and the separation gas nozzle 42.

The second evacuation opening 62 is formed, between the second process gas nozzle 32 and the convex portion 4 on the downstream side in the rotational direction of the turntable 2 relative to the second process gas nozzle 32, at a location closer to the separating area D side. Hence, the first evacuation opening 62 is also arranged so as to be in communication with the gas retention space S2 between the second evacuation opening 61 and the separation gas nozzle 41. The first evacuation opening 61 is to evacuate the Si-containing gas and the separation gas, and the second evacuation opening 62 is to evacuate the O₃ gas and the separation gas. As shown FIG. 1, these first evacuation opening 61 and the second evacuation opening 62 are respectively connected to, for example, vacuum pumps 64 to be vacuum evacuation mechanisms by evacuation pipes 63 including pressure controllers 65 such as butterfly valves in the middle thereof.

As shown in FIG. 1, a heater unit 7 is provided in a space between the turntable 2 and the bottom portion 14. The wafer W on the turntable 2 can be heated to, for example, 300° C. through the turntable 2. In FIG. 1, a cover member 71a is provided on the lateral side of the heater unit 7, and a cover member 7a covers the upper side of this heater unit 7. Furthermore, on the bottom portion 14 of the vacuum chamber 1, purge gas supplying pipes 73 to purge a space in which the heater unit 7 is arranged below the heater unit 7 are provided at plural places through the circumferential direction.

As shown in FIGS. 2 and 3, the transfer opening 15 to transfer the wafer W between an external transfer arm (not shown in the drawing) and the turntable 2 is formed in the side wall of the vacuum chamber 1, and the transfer opening 15 is configured to be hermetically openable and closeable by a gate valve G. In addition, because the wafer W is transferred into or from the concave portions 24 at a position facing the transfer opening 15 with the transfer arm, lift pins for transfer to lift up the wafer W from the backside by penetrating through the concave portions 24 and the lifting mechanism (none of which are shown in the drawing) are provided at the position corresponding to the transfer position below the turntable 2.

Moreover, a control part 120 constituted of a computer to control operation of the whole apparatus is provided in this film deposition apparatus, and a program to implement a film deposition process described below is stored in a memory of the control part 120. This program is constituted of instructions of step groups to cause the apparatus to implement respective operations of the apparatus, and is installed from a memory unit 121 to be a storage medium such as a hard disk, a compact disc, a magnetic optical disc, a memory card and a flexible disc into the control part 120.

Next, a description is given about an action of the above-mentioned embodiment. First, the gate valve G is opened, and for example, five wafers W are loaded on the turntable 2 through the transfer opening 15 by the not shown transfer arm, while rotating the turntable 2 intermittently. Next, the gate valve G is closed; the inside of the vacuum chamber 1 is evacuated by the vacuum pump 64; and the wafer W is heated, for example, to 300° C. by the heater unit 7, while rotating the turntable 2 in a clockwise fashion.

Subsequently, the first process gas nozzle 31 discharges a Si-containing gas, and the second process gas nozzle 32 discharges an O₃ gas. Furthermore, a separation gas is discharged from the separation gas nozzles 41, 42 at a predetermined flow rate, and an N₂ gas is discharged from a separation gas supplying pipe 51 and the purge gas supplying pipes 72, 72 at a predetermined flow rate. Then, the pressure controller 65 adjusts a pressure in the vacuum chamber 1 at a preliminarily set processing pressure.

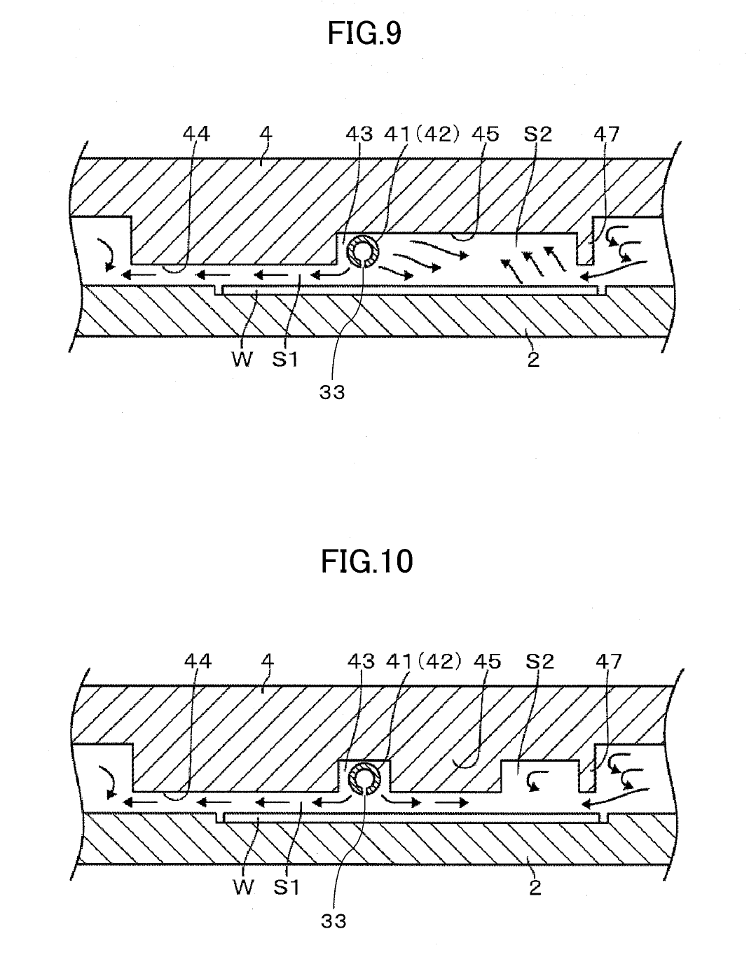

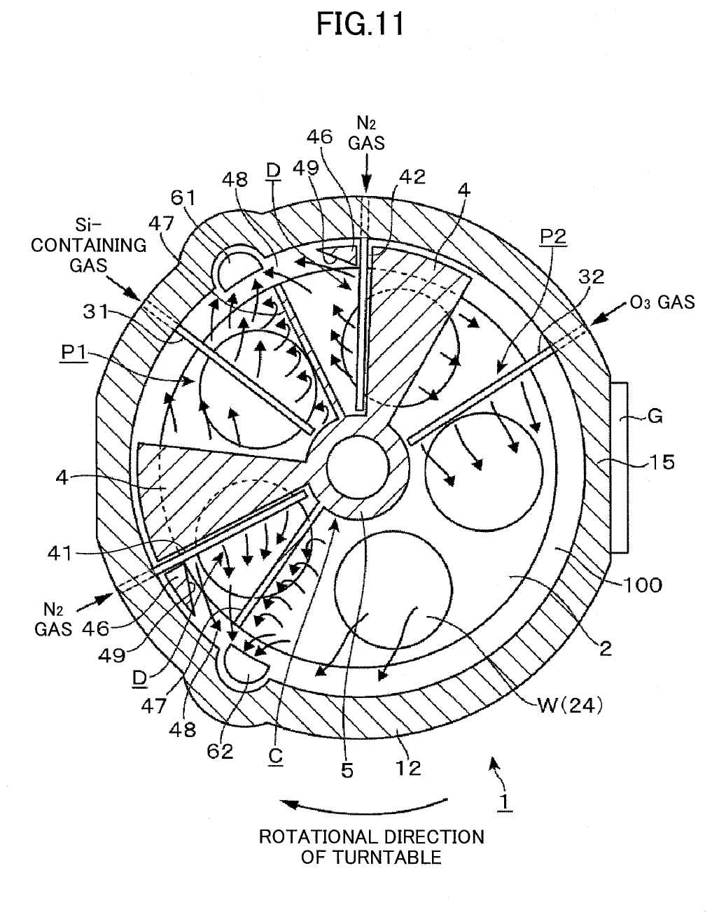

The process gas supplied from the process gas nozzles 31, 32 into the vacuum chamber 1 are induced to reach the convex portion 4 on the downstream side by, for example, the rotation of the turntable 2. At this time, as shown in FIGS. 9 through 11, because the wall surface portion 47 is formed on the upstream side of the rotational direction of the turntable 2 in the convex portion 4 as discussed above, the process gases having reached the convex portion 4 collide with the wall surface portion 47, and most of the process gases are evacuated toward the outer edge side of the turntable 2 (i.e., evacuation openings 61, 62).

On the other hand, a part of the process gas flows under the wall surface portion 47 and intrudes into the gas retention space S2. As discussed above, because the gas retention space S2 is larger than the narrow space between the wall surface portion 47 and the turntable 2, the gas having intruded into the gas retention space S2 from the lower side of the wall surface portion 47 decreases its flow speed compared to the flow speed before reaching the gas retention space S2, and in a sense, stagnates in the gas retention space S2. Moreover, because the narrow space S1 is formed on the downstream side of the gas retention space S2, and makes it difficult for the gas to enter, the process gas having intruded into the gas retention space S2 is likely to circulate toward the opening portion 48 to be a space larger than the narrow space S1.

At this time, while the narrow space S1 is formed on the downstream side as seen from the separation nozzles 41, 42, the gas retention space S2 larger than the narrow space S1 is formed on the upstream side. Accordingly, most of the separation gases discharged from the separation gas nozzles 41, 42 circulate toward the gas retention space S2 to be a large space, in a sense, in a direction opposite to the rotational direction of the turntable 2. This causes the process gases having entered the gas retention space S2 to be evacuated toward the evacuation openings 61, 62 through the opening portions 48 together with the separation gases.

In addition, since the guide surfaces 49 are provided in the gas retention space S2, the process gases and the separation gases that circulate from the gas retention space S2 toward the evacuation openings 61, 62 are guided by the guide surfaces 49, thereby suppressing, for example, disturbed flow and stagnation. Moreover, with respect to the O₃ gas flowing around the outer edge side of the convex portion 4 and attempting to go to the process area P1 (P2), the gas flow is regulated by the guide surface 49, and evacuated toward the evacuation openings 62 (61). Furthermore, because a part of the separation gases supplied from the separation gas nozzles 41, 42 respectively discharges to the downstream side through the narrow space S1, the intrusion of the process gases from the downstream side into the narrow space S1 is prevented. Accordingly, the respective gases are evacuated without being mixed with each other in the processing atmosphere in the vacuum chamber 1.

In addition, since the purge gas is supplied to the lower side of the turntable 2, the gas attempting to diffuse into the lower side of the turntable 2 is pushed back toward the evacuation openings 61, 62 sides by the purge gas.

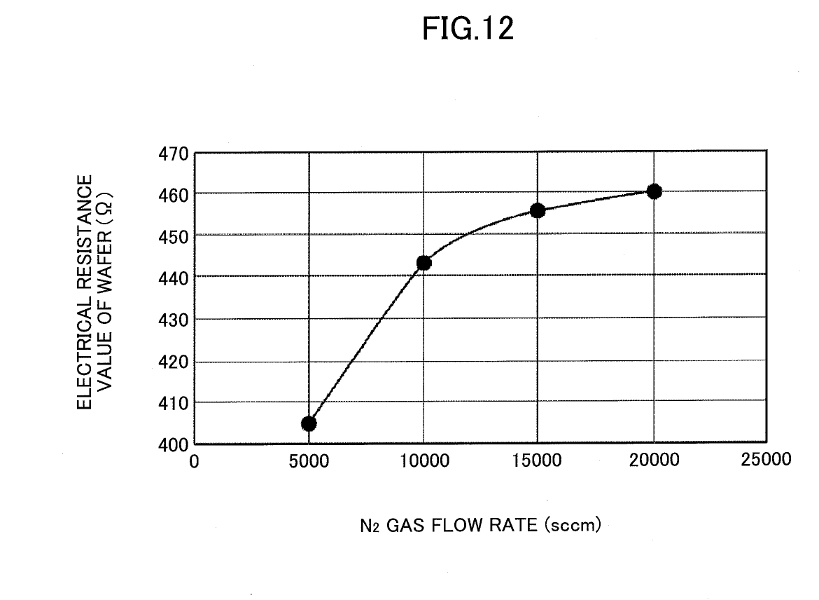

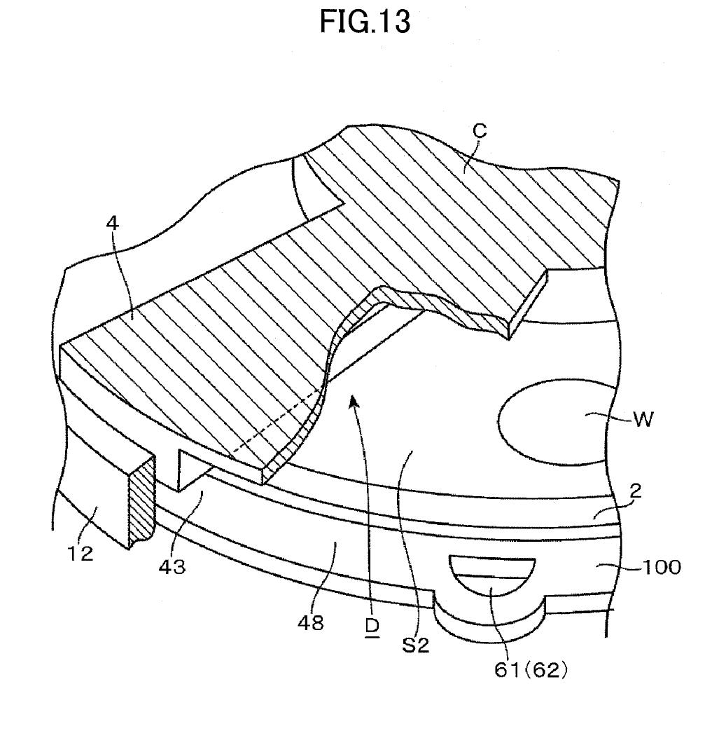

In the meanwhile, the wafer W reaches the first process area P1 by the rotation of the turntable 2 and the Si-containing gas is adsorbed on the surface of the wafer W in the first process area P1. Next, in the second process area P2, the Si-containing gas having been adsorbed on the surface of the wafer W is oxidized by the O₃ gas, and one or more molecular layers of a silicon oxide film (Si—O) to be a film component are formed, which finally forms a reaction product. At this time, because the mixture of the process gases with each other is prevented as discussed above, and furthermore the respective process gases becomes difficult to be diluted in the process areas P1, P2 by reducing the flow rate of the separation gases, the reaction product formed on the wafer W has a favorable electrical characteristic due to occurrence of a favorable reaction (i.e., oxidation of the Si-containing gas), as noted in FIG. 12 shown below. In this manner, by the rotation of the turntable 2, the reaction product with a favorable electrical characteristic is deposited in a layer-by-layer manner thereby to form a thin film.

According to the above embodiment, the separation gas nozzles 41, 42 are arranged between the process areas P1, P2, and the process areas P1, P2 are separated by supplying the separation gases from the separation gas nozzles 41, 42. At this time, on the downstream side in the rotational direction of the turntable 2 in the separation gas nozzles 41, 42, the first ceiling surfaces 44 are respectively provided to form the narrow spaces S1 between the upper surface of the turntable 2 and the first ceiling surfaces 44. Moreover, on the upstream side in the rotational direction of the turntable 2 in the first ceiling surfaces 44, the second ceiling surfaces 45 higher than the first ceiling surfaces 44 are respectively provided so as to be adjacent to the first ceiling surfaces 44. This makes it difficult for the process gases in the gas retention spaces S2 that are areas between the second ceiling surfaces 45 and the turntable 2 to enter the narrow spaces S1 on the downstream side. Furthermore, since the separation gases are supplied to areas between these areas S1, S2, the process gases are evacuated toward the evacuation openings 61, 62 that are in communication with the gas retention spaces S2 with the separation gases. Hence, a supply flow rate of the separation gases can be reduced, preventing the process gases from being mixed with each other in the processing atmosphere. This can suppress the respective process gases from being diluted by the separation gases in the process areas P1, P2, which can cause a thin film having a favorable film quality to be formed. In addition, reducing occurrence of particles in the processing atmosphere is possible.

In other words, in a conventional method, the process areas P1, P2 are separated from each other by creating a very narrow space (narrow space S1) between the process areas P1, P2, and by forming a flow of a separation gas at a fast flow speed. Hence, in such a method, if the flow rate of the separation gas is extremely decreased, the flow speed of the separation gas becomes slow, which could slightly decrease the effect of separating the process areas P1, P2 from each other. On the other hand, when the flow rate of the separation gas is set at a large amount, even if the mixture of the respective process gases with each other can be prevented, there is a concern that a sufficient reaction (i.e., adsorption of the Si-containing gas or oxidation of the gas) cannot occur on the surface of a wafer W due to dilution of the respective process gases caused by the separation gas in the process areas P1, P2.

Therefore, in the embodiment of the present invention, by forming the gas retention spaces S2 larger than such narrow spaces S1 on the upstream sides of the separation gas nozzles 41, 42, most of the separation gases respectively discharged from the separation gas nozzles 41, 42 are led to circulate to the gas retention space S2. Accordingly, in the gas retention space S2, the gas flow in the direction opposite to the rotational direction of the turntable 2 is formed as discussed above, thereby the process gases having entered the gas retention spaces S2 can be rapidly evacuated. By doing this, the separation effect of the process areas P1, P2 can be improved, even if the flow rate of the separation gases is reduced compared to the conventional method. At this time, since a part of the process gases supplied from the separation gas nozzles 41, 42 pass the narrow space S1 and flow out to the downstream sides, the intrusion of the process gases can be naturally prevented in the narrow spaces S1.

FIG. 12 shows a measurement result of electric resistance of thin films obtained under various conditions when the thin films were deposited under the various conditions where the flow rate of the separation gases supplied from the separation gas nozzles 41, 42 are varied. This experiment shows an example of a Ti—N (titanium nitride) film being deposited by using TiCl₄ (titanium chloride) gas and an NH₃ (ammonia) gas as the first process gas and the second process gas respectively. It is noted that the electrical resistance increases and the film quality degrades as the flow rate of the separation gases increases. On the other hand, when the flow rate of the separation gases is low (e.g., 10000 sccm or less), the electrical resistance is low and the film quality is favorable. In other words, it is noted that the NH₃ gas is diluted and the TiCl₄ gas adsorbed on the wafer W cannot be sufficiently azotized when the flow rate of the separation gas is high. Therefore, as discussed above, by preventing the respective process gases from being mixed with each other while the flow rate is kept low, the dilution of the process gases can be suppressed and a thin film with a favorable film quality can be obtained.

In the above example, the wall surface portion 47 is provided at the concave portion 4 and the guide surface 49 is arranged, but as shown in FIG. 13, these wall surface portion 47 and guide surface 49 may not be provided. More specifically, for example, if the separation gas nozzle 41 is taken as an example, in the convex portion 4 on the right side (i.e., the upstream side) of the both sides of the convex portions 4, 4 of the separation gas nozzle 41, the gas retention space S2 may be formed across the rotational and radial directions of the turntable 2.

Moreover, the second ceiling surface 45 may be made the same height as the ceiling surface of the areas in which the process gas nozzles 31, 32 are arranged. Furthermore, in the above example, the gas discharge ports 33 of the separation gas nozzles 41, 42 are formed to face the underside, but the gas discharge ports 33 maybe formed to face the lower and upstream side in the rotational direction of the turntable 2. In addition, the evacuation openings 61, 62 may be formed in the side surface of the vacuum chamber 1 instead of being provided in the side ring 100. Moreover, the guide surface 49 is formed vertically in the above example, but for example, the guide surface 49 may be slanted relative to the vertical place so that the guide surface 49 faces downward.

In this embodiment, the higher the rotational speed of the turntable 2 becomes, the more readily the process gases mingle with each other, and the higher the flow rate of the respective process gases becomes, the more easily the process gases intrude into the separating areas D. Accordingly, the embodiment of the present invention can obtain a great effect in particular when the rotational speed of the turntable 2 is 5 rpm or less, or with respect to the flow rates of the respective process gases, the Si-containing gas is 50 sccm or more, and the O₃ gas is 5000 sccm or more. Furthermore, an example of the flow rates of the separation gases respectively supplied from the separation gas nozzles 41, 42 is 1000 to 10000 sccm, and 10000 to 40000*Qsccm if defined by a flow rate Q of the process gases (i.e., the total flow rate of the Si-containing gas and the O₃ gas).

As the separation gases, instead of the N₂ gas, or with the N₂ gas, an inactive gas such as an Ar gas may be used.

As the substrate processing apparatus in accordance with the embodiment of the present invention, the film deposition apparatus is taken as the above-discussed example, but may be configured to be another apparatus such as an apparatus that performs an etching process other than the film deposition apparatus. In this case, as the first process gas, for example, a Br (bromine)-system etching gas to etch a poly silicon film is used, and as the second process gas, for example, a CF-system etching gas to etch a silicon oxide film is used. Then, in the respective process areas P1, P2, plasma sources that apply radio frequency power are installed in order to convert the respective plasma gases to plasma.

On the wafer W, for example, the poly silicon film and the silicon oxide film are alternately deposited in a layer-by-layer manner as multiple layers, and a resist film in which a hole and a trench are patterned is formed. When an etching process is performed on the wafer W by using the above-discussed substrate processing apparatus, for example, in the first processing area P1, the poly silicon film of the upper layer side is etched through the resist film. Next, in the second process area P2, the silicon oxide film on the lower layer side of the poly silicon film is etched through the resist film. In this way, the multiple-layer films are etched through the common resist film from the upper layer side to the lower layer side in order. Even in this case, because the separating areas D are provided between the process areas P1, P2, the mixture of the process gases with each other is prevented, and a favorable etching is implemented by allowing the separation gases to suppress the process gases from being diluted.

In this manner, a film deposition apparatus and a substrate processing apparatus according to embodiments of the present invention include separation gas nozzles that extend from the center side to the outer circumference side of a turntable and are arranged between process areas to which process gases are respectively supplied, and the process areas are separated from each other by supplying separation gases from the separation gas nozzles. Moreover, first ceiling surfaces 44 are provided on the downstream side in a rotational direction of the turntable relative to the separation gas nozzles to form narrow spaces between the upper surface of the turntable and the lower surface of the first ceiling surfaces. Furthermore, second ceiling surfaces higher than the first ceiling surfaces are provided so as to be adjacent to the first ceiling surfaces on the upstream side in the rotational direction of the turntable relative to the separation gas nozzles. This makes it difficult for the process gases in gas retention spaces that are areas between the second ceiling surfaces and the turntable to enter the narrow spaces on the downstream side, and because the separation gases are supplied to locations between these spaces, the process gases in the gas retention spaces are evacuated with the separation gases toward evacuation openings that are in communication with the gas retention spaces. Therefore, a supply flow rate of the separation gases can be reduced, preventing the process gases from being mixed with each other in processing atmospheres.

All examples recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention. cm What is claimed is:

1. A film deposition apparatus configured to form a thin film on a wafer by repeating a cycle of supplying plural kinds of process gases in turn in a vacuum chamber, the film deposition apparatus comprising:
a turntable having a substrate mounting area in an upper surface to hold a substrate thereon in a circumferential direction, the turntable being configured to make the substrate mounting area revolve in the vacuum chamber;
a plurality of process gas supplying parts configured to supply process gases different from each other to process areas spaced apart from each other in the circumferential direction of the turntable; and
at least one separation part including a separation gas nozzle arranged to extend from a center side to an outer circumference side of the turntable to supply a separation gas to a separating area formed between the process areas for separating atmospheres of the respective process areas; and
at least one evacuation opening configured to evacuate an atmosphere in the vacuum chamber, the evacuation opening being provided at an outer edge side of the turntable,
wherein the separation part includes a first ceiling surface provided on the downstream side in the rotational direction of the turntable relative to the separation gas nozzle, the first ceiling surface being configured to form a narrow space between a lower surface thereof and the upper surface of the turntable from the center side to the outer circumference side of the turntable, and
a second ceiling surface provided on the upstream side in the rotational direction of the turntable relative to the separation gas nozzle, the second ceiling surface being configured to be higher than the first ceiling surface from the center side to the outer circumference side, and
wherein the evacuation opening is in communication with a gas retention space to form an area between the second ceiling surface and the turntable.

2. The film deposition apparatus as claimed in claim 1, further comprising:
a wall surface portion extending from the second ceiling surface toward the turntable and formed across from the center side to the outer circumference side on the upstream side in the rotational direction of the turntable relative to the gas retention space, in order to prevent the process gases from entering the gas retention space.

3. The film deposition apparatus as claimed in claim 1, further comprising:
a guide surface extending from a lateral side toward the evacuation opening so as to intersect with a length direction of the separation gas nozzle and provided between an outer edge portion and an inner wall of the vacuum chamber on the outside of the gas retention space, in order to guide the separation gas discharged from the separation gas nozzle.

4. The film deposition apparatus as claimed in claim 1,
wherein the at least one separation part includes plural separation parts provided between the respective process areas, and
wherein the at least one evacuation opening includes plural evacuation openings provided corresponding to respective plural of the separation parts.

5. A substrate processing apparatus configured to perform a process on a wafer by repeating a cycle of supplying plural kinds of process gases in turn in a vacuum chamber, the substrate processing apparatus comprising:
a turntable having a substrate mounting area in an upper surface to hold a substrate thereon in a circumferential direction, the turntable being configured to make the substrate mounting area revolve in the vacuum chamber;
a plurality of process gas supplying parts configured to supply process gases different from each other to process areas spaced apart from each other in the circumferential direction of the turntable; and
at least one separation part including a separation gas nozzle arranged to extend from a center side to an outer circumference side of the turntable to supply a separation gas to a separating area formed between the process areas for separating atmospheres of the respective process areas; and
at least one evacuation opening configured to evacuate an atmosphere in the vacuum chamber, the evacuation opening being provided at an outer edge side of the turntable,
wherein the separation part includes a first ceiling surface provided on the downstream side in the rotational direction of the turntable relative to the separation gas nozzle, the first ceiling being configured to form a narrow space between a lower surface thereof and the upper surface of the turntable from the center side to the outer circumference side of the turntable, and
a second ceiling surface provided on the upstream side in the rotational direction of the turntable relative to the separation gas nozzle, the second ceiling surface being configured to be higher than the first ceiling surface from the center side to the outer circumference side, and
wherein the evacuation opening is in communication with a gas retention space to be an area between the second ceiling surface and the turntable.

6. The substrate processing apparatus as claimed in claim 5, further comprising:
a wall surface portion extending from the second ceiling surface toward the turntable and formed across from the center side to the outer circumference side on the upstream side in the rotational direction of the turntable relative to the gas retention space, in order to prevent the process gases from entering the gas retention space.

7. The substrate processing apparatus as claimed in claim 5, further comprising:
a guide surface extending from a lateral side toward the evacuation opening so as to intersect with a length direction of the separation gas nozzle and provided between an outer edge portion and an inner wall of the vacuum chamber on the outside of the gas retention space, in order to guide the separation gas discharged from the separation gas nozzle.

8. The substrate processing apparatus as claimed in claim 5,
wherein the at least one separation part includes plural separation parts provided between the respective process areas, and
wherein the at least one evacuation opening includes plural evacuation openings provided corresponding to respective plural of the separation parts.
